(19) United States
(12) Patent Application Publication
(10) Pub. No.: US 2026/0303193 A1
(43) Pub. Date: Oct. 1, 2026

(54) RECEPTION DEVICE, RECEPTION METHOD, AND TRANSMISSION/RECEPTION SYSTEM

(71) Applicant: SONY SEMICONDUCTOR SOLUTIONS CORPORATION, KANAGAWA (JP)

(72) Inventors: KANJI ABE, KANAGAWA (JP); YUYA ISHIGURO, KANAGAWA (JP)

(21) Appl. No.: 18/880,557

(22) PCT Filed: May 18, 2023
(86) PCT No.: PCT/JP2023/018588

§ 371 Date: Jan. 1, 2025

(30) Foreign Application Priority Data
Jul. 14, 2022 (JP) 2022-112866

(51) Int. Cl. H04B 7/08; H01Q 21/29

(52) U.S. Cl. CPC H04B 7/08; H01Q 21/29

(57) ABSTRACT

Provided is a reception device including: an antenna component including a plurality of antenna elements that receives a predetermined radio wave transmitted from a predetermined transmission device, and a transmission line that connects the plurality of antenna elements in series and transmits a radio wave received by each of the antenna elements; a correlator that acquires the radio wave via the transmission line and calculates a correlation between the radio wave received by each of the antenna elements and the predetermined radio wave; and an arrival direction calculation unit that calculates an arrival direction of the radio wave on the basis of the calculated correlation.

### FIELD

The present disclosure relates to a reception device, a reception method, and a transmission/reception system.

### BACKGROUND

In recent years, various techniques for calculating an arrival direction of a radio wave have been proposed. For example, Patent Literature 1 below discloses a technique in which four antenna elements are disposed at vertices of a rectangle or a parallelogram, incoming radio waves are detected by the four antenna elements to calculate an arrival direction of the radio waves on the basis of a time difference of arrival of the radio waves between the antenna elements. Specifically, in a configuration of an antenna component proposed in Patent Literature 1 below, a phase detector is provided in each of the plurality of antenna elements, and a transmission line individually connects each antenna element to each phase detector.

### CITATION LIST

### Patent Literature

Patent Literature 1: JP H6-308212 A

### SUMMARY

### Technical Problem

However, the technique proposed in Patent Literature 1 has restrictions on antenna design such as an antenna element interval, needs to provide a phase detector in each antenna element, and thus, inevitably has complicated configuration. Furthermore, in the technique proposed in Patent Literature 1, when a radio wave to be targeted has high frequency, it is necessary to narrow an interval between the antenna elements, and thus, it is highly probable that a plurality of antenna elements is shielded at the same time. Therefore, in the technique proposed in Patent Literature 1, since a radio wave cannot be stably received, it is difficult to stably calculate an arrival direction thereof.

Therefore, the present disclosure proposes a reception device, a reception method, and a transmission/reception system enabling stable calculation of an arrival direction of a radio wave with less restriction in antenna design and with a simple configuration.

### Solution to Problem

According to the present disclosure, there is provided a reception device including: an antenna component including a plurality of antenna elements that receives a predetermined radio wave transmitted from a predetermined transmission device, and a transmission line that connects the plurality of antenna elements in series and transmits a radio wave received by each of the antenna elements; a correlator that acquires the radio wave via the transmission line and calculates a correlation between the radio wave received by each of the antenna elements and the predetermined radio wave; and an arrival direction calculation unit that calculates an arrival direction of the radio wave on the basis of the calculated correlation.

Furthermore, according to the present disclosure, there is provided a reception method. In the reception method, a reception device: receives a predetermined radio wave transmitted from a predetermined transmission device via a plurality of antenna elements; acquires the radio wave via a transmission line that connects the plurality of antenna elements in series and transmits a radio wave received by each of the antenna elements; calculates a correlation between the radio wave received by each of the antenna elements and the predetermined radio wave; and calculates an arrival direction of the radio wave on the basis of the calculated correlation.

Furthermore, according to the present disclosure, there is provided a transmission/reception system including: a transmission device and a reception device. In the transmission/reception system, the reception device has: an antenna component including a plurality of antenna elements that receives a predetermined radio wave transmitted from the transmission device, and a transmission line that connects the plurality of antenna elements in series and transmits a radio wave received by each of the antenna elements; a correlator that acquires the radio wave via the transmission line and calculates a correlation between the radio wave received by each of the antenna elements and the predetermined radio wave; and an arrival direction calculation unit that calculates an arrival direction of the radio wave on the basis of the calculated correlation.

### BRIEF DESCRIPTION OF DRAWINGS

FIG. 1 is a block diagram illustrating a transmission/reception system 1 according to a first embodiment of the present disclosure.

FIG. 2 is a schematic diagram of a transmission signal according to the first embodiment of the present disclosure.

FIG. 3 is a block diagram illustrating a reception device 20 according to the first embodiment of the present disclosure.

FIG. 4 is an explanatory diagram (part 1) for explaining the first embodiment of the present disclosure.

FIG. 5 is an explanatory diagram (part 2) for explaining the first embodiment of the present disclosure.

FIG. 6 is an explanatory diagram (part 3) for explaining the first embodiment of the present disclosure.

FIG. 7 is an explanatory diagram (part 4) for explaining the first embodiment of the present disclosure.

FIG. 8 is a schematic diagram illustrating an antenna component 200 according to the first embodiment of the present disclosure.

FIG. 9 is a schematic diagram illustrating an antenna component 200a according to a modification example of the first embodiment of the present disclosure.

FIG. 10 is a block diagram illustrating a reception device 20a according to a second embodiment of the present disclosure.

FIG. 11 is an explanatory diagram for explaining the second embodiment of the present disclosure.

FIG. 12 is a block diagram illustrating a reception device 20b according to a third embodiment of the present disclosure.

FIG. 13 is a block diagram illustrating a reception device 20c according to a fourth embodiment of the present disclosure.

FIG. 14 is an explanatory diagram for explaining the fourth embodiment of the present disclosure.

FIG. 15 is a block diagram illustrating a reception device 20d according to a fifth embodiment of the present disclosure.

FIG. 16 is an explanatory diagram for explaining the fifth embodiment of the present disclosure.

FIG. 17 is an explanatory diagram for explaining an application example 1 of the embodiment of the present disclosure.

FIG. 18 is an explanatory diagram for explaining an application example 2 of the embodiment of the present disclosure.

### DESCRIPTION OF EMBODIMENTS

In the following, preferred embodiments of the present disclosure will be described in detail with reference to the accompanying drawings. Note that, in the present specification and the drawings, components having substantially the same functional configuration are denoted by the same reference numeral to omit redundant description thereof. In addition, in the present specification and the drawings, a plurality of components having substantially the same or similar functional configuration may be distinguished by attaching different alphabets after the same reference numeral. However, in a case where it is not particularly necessary to distinguish each of a plurality of components having substantially the same or similar functional configuration, only the same reference numeral is attached.

In addition, the drawings referred to in the following description are drawings for promoting description of the embodiments of the present disclosure and understanding thereof, and shapes, dimensions, ratios, and the like illustrated in the drawings may be different from actual ones for the sake of clarity. Furthermore, a display device illustrated in the drawings, components included in the display device, and the like can be appropriately modified in design in consideration of the following description and known techniques.

In the following description, expression of shapes of an electrode and the like on a laminate constituting an antenna component does not only mean geometrically defined shapes, but also includes a shape with an allowable difference in securing characteristics of the antenna and the like or a shape similar to that shape.

Furthermore, in the following description of the circuit configuration, unless otherwise specified, “connection” means electrically connecting a plurality of elements. Furthermore, “connection” in the following description includes not only a case of directly and electrically connecting a plurality of elements but also a case of indirectly connecting a plurality of elements via other element.

Note that the description will be given in the following order.
1. Background Leading to Creation of Embodiments of Present Disclosure
2. First Embodiment
2.1 Transmission/Reception System
2.2 Calculation Method
2.3 Antenna Component
3. Second Embodiment
3.1 Reception Device
3.2 Calculation Method
4. Third Embodiment
5. Fourth Embodiment
5.1 Reception Device
5.2 Calculation Method
6. Fifth Embodiment
7. Conclusion
8. Application Example
9. Supplement

### 1. Background Leading to at Creation of Embodiments of Present Disclosure

First, before describing embodiments of the present disclosure, a background leading to creation of the embodiments of the present disclosure by the present inventor will be described.

As described above, in recent years, various techniques for calculating an arrival direction of a radio wave have been proposed. For example, Patent Literature 1 above discloses a technique in which four antenna elements are disposed at vertices of a rectangle or a parallelogram, incoming radio waves are detected by the four antenna elements to calculate an arrival direction of the radio waves on the basis of a time difference of arrival of the radio waves between the antenna elements.

However, in the technique proposed in Patent Literature 1, it is necessary to provide a phase detector in each of the plurality of antenna elements and to individually wire each antenna element to each phase detector with a transmission line. Furthermore, in order to make a phase relationship between the phase detectors known, it is necessary to make the transmission lines equal in length, i.e., the technique proposed in Patent Literature 1 has many restrictions on configuration, design, and the like, and inevitably has complicated configuration.

The technique proposed in Patent Literature 1 further has a restriction that an interval between the antenna elements needs to be a half wavelength of a radio wave, so that the interval between the antenna elements cannot be set to a desired arbitrary length. In particular, when a target radio wave has a frequency as high as 8 GHz or more, for example, the interval between the antenna elements is reduced to 1.5 cm in the technique proposed in Patent Literature 1. In such a case, since the interval between the antenna elements is narrowed, it is highly probable that the plurality of antenna elements is shielded at the same time. Therefore, in the technique proposed in Patent Literature 1, since a radio wave cannot be stably received, it is difficult to stably calculate an arrival direction thereof.

Therefore, in view of such a situation, the present inventor has created the embodiments of the present disclosure described below. According to the embodiments of the present disclosure created by the present inventor, there are few restrictions on antenna design, and a probability that a plurality of antenna elements is shielded at the same time is reduced while having a simple configuration. Therefore, an arrival direction of a radio wave can be stably calculated by an antenna diversity effect. Here, antenna diversity is assumed to mean to improve reception quality and reliability by receiving radio waves by two or more antenna elements. In the following, details of such embodiments of the present disclosure created by the present inventor will be sequentially described.

### 2. First Embodiment

### <2.1 Transmission/Reception System>

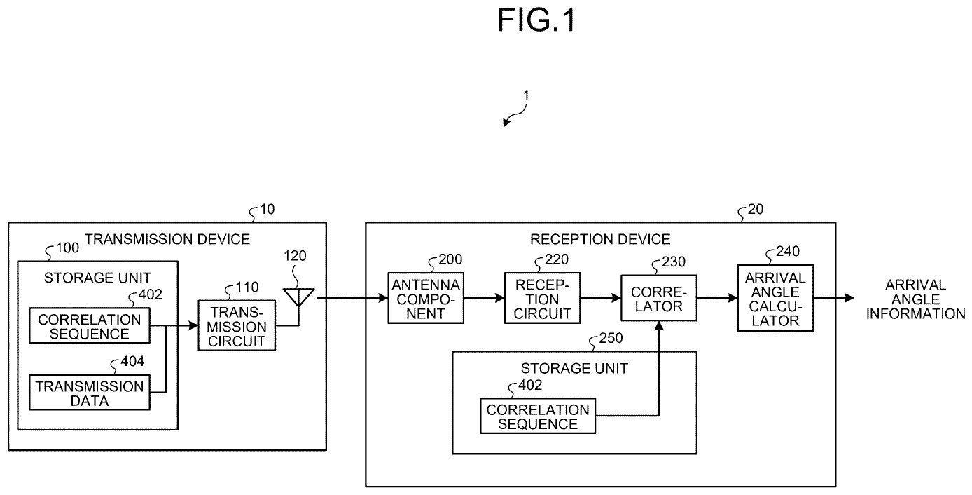

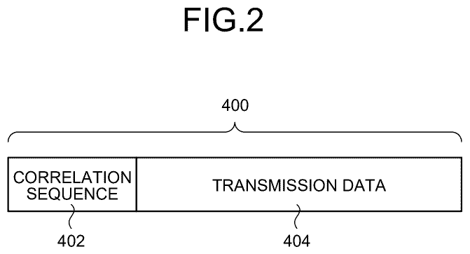

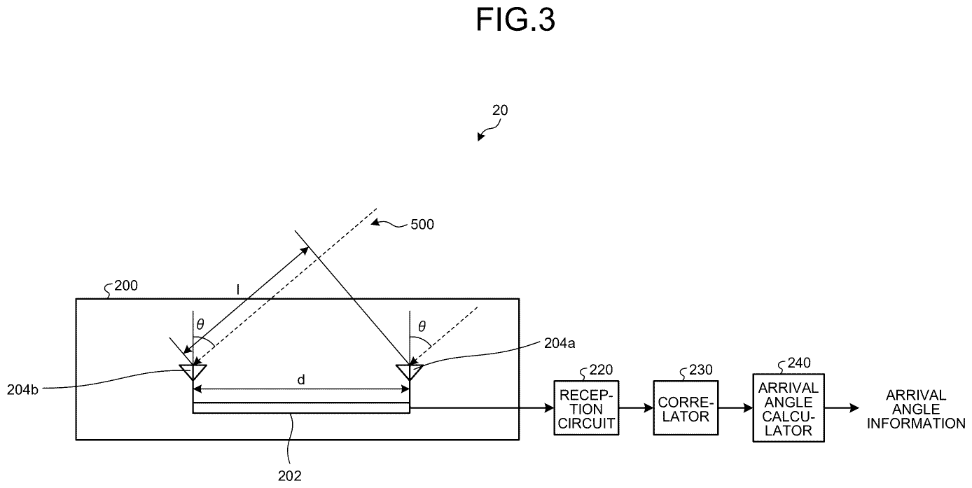

First, a configuration of a transmission/reception system 1 according to a first embodiment of the present disclosure will be described with reference to FIGS. 1 and 2. FIG. 1 is a block diagram of the transmission/reception system 1 according to the present embodiment, and FIG. 2 is a schematic diagram of a transmission signal according to the present embodiment.

As illustrated in FIG. 1, the transmission/reception system 1 according to the present embodiment includes a transmission device 10 and a reception device 20. In the following, a configuration of each device included in the transmission/reception system 1 according to the present embodiment will be sequentially described.

### (Transmission Device 10)

As illustrated in FIG. 1, the transmission device 10 mainly includes a storage unit 100, a transmission circuit 110, and a transmission antenna 120. In the following, each functional unit of the transmission device 10 will be sequentially described.

### ~Storage Unit 100~

The storage unit 100 can be implemented by a read only memory (ROM), a random access memory (RAM), or the like that stores various control programs executed by the transmission device 10, various parameters, and the like. In the present embodiment, the storage unit 100 may store a correlation sequence 402, transmission data 404, and the like as illustrated in FIG. 1. Details of the stored information will be described later.

### ~Transmission Circuit 110~

The transmission circuit 110 can convert a transmission signal (predetermined radio wave) 400 (see FIG. 2) into a high frequency signal having a desired carrier frequency via the transmission antenna 120 to be described later, and transmit the high frequency signal to the reception device 20. In the present embodiment, the high frequency signal has a frequency of, for example, 3 GHz to 10 GHz. In addition, the transmission circuit 110 can be configured with, for example, an oscillator (not illustrated) that generates a local oscillation signal having a desired frequency, a mixer (not illustrated) that converts a frequency of the transmission signal 400, a bandpass filter (BPF) (not illustrated) that selectively passes a signal having a desired frequency, a power amplifier (PA) (not illustrated) that amplifies the transmission signal 400, and the like.

### ~Transmission Antenna 120~

The transmission antenna 120 can radiate the high frequency signal converted by the transmission circuit 110 into space.

Note that the transmission device 10 is not limited to the configuration illustrated in FIG. 1. For example, although not illustrated in FIG. 1, the transmission device 10 may have a control circuit unit including an arithmetic theoretical operation element such as, for example, a digital signal processor (DSP), a field-programmable gate array (FPGA), or a microcomputer. The control circuit unit can generate, for example, transmission data 404 (see FIG. 2) included in the transmission signal 400.

### (Reception Device 20)

As illustrated in FIG. 1, the reception device 20 mainly includes an antenna component 200, a reception circuit 220, a correlator 230, an arrival angle calculator (arrival direction calculation unit) 240, and a storage unit 250. In the following, each functional unit of the reception device 20 will be sequentially described.

### ~Antenna Component 200~

The antenna component 200 includes a plurality of antenna elements 204 that receives the transmission signal from the transmission device 10, and a transmission line 202 that connects the plurality of antenna elements 204 in series and transmits the transmission signal 400 received by each antenna element 204 to the reception circuit 220 to be described later. A detailed configuration of the antenna component 200 will be described later.

### ~Reception Circuit 220~

The reception circuit 220 is provided between the transmission line 202 of the antenna component 200 and the correlator 230 to be described later. The reception circuit 220 receives the transmission signal 400 which is the high frequency signal from the transmission device 10 via the antenna component 200, converts the received transmission signal 400 into a baseband signal having a low frequency, and outputs the baseband signal to the correlator 230 to be described later. The reception circuit 220 can be configured with, for example, a low noise amplifier (LNA) (not illustrated) that amplifies a signal, a BPF (not illustrated) that selectively passes a signal having a desired frequency, a mixer (not illustrated) that converts a frequency of a signal, and the like.

~Correlator 230~

The correlator 230 calculates a correlation between a signal received by each antenna element 204 and the transmission signal 400 from the transmission device 10, and outputs a calculation result to the arrival angle calculator 240. For example, the correlator 230 can be configured with, for example, an arithmetic theoretical operation element such as a DSP, an FPGA, or a microcomputer.

Specifically, in the present embodiment, it is assumed that the transmission device 10 and the reception device 20 have agreed on the correlation sequence 402, i.e., the transmission device 10 and the reception device 20 store the common correlation sequence 402 in advance. Then, in the present embodiment, the correlation sequence 402 having a predetermined signal pattern can be included at a head of the transmission signal 400 transmitted from the transmission device 10 as will be described later. Therefore, in the present embodiment, the transmission signal 400 received by the reception device 20 can also include the correlation sequence 402 having a similar predetermined signal pattern.

Therefore, the correlator 230 according to the present embodiment calculates a cross-correlation characteristic (a degree of coincidence between both signal patterns) (correlation) between the correlation sequence 402 having a known signal pattern stored in the storage unit 250 serving as an answer and a signal pattern of the signal received by the reception device 20. Then, the correlator 230 calculates reception time when the reception device 20 receives the transmission signal 400 by detecting timing at which a correlation value becomes the highest (matching of both the signal patterns is the highest).

### ~Arrival Angle Calculator 240~

The arrival angle calculator 240 calculates an incident angle of the transmission signal 400 with respect to the antenna component 200, i.e., an arrival angle (arrival direction), using a difference in arrival time of the transmission signal 400 in the plurality of antenna elements 204 obtained by the cross-correlation characteristic calculated by the correlator 230 and using a length of the transmission line 202 between the plurality of antenna elements 204. For example, the arrival angle calculator 240 can be configured with, for example, an arithmetic theoretical operation element such as a DSP, an FPGA, or a microcomputer. Note that details of a method of calculating an arrival angle in the arrival angle calculator 240 will be described later.

### ~Storage Unit 250~

The storage unit 250 can be realized by a ROM, a RAM, or the like that stores various control programs executed by the reception device 20, various parameters, and the like. In the present embodiment, for example, the storage unit 250 may store in advance the correlation sequence 402 and the like as illustrated in FIG. 1.

Note that the reception device 20 is not limited to the configuration illustrated in FIG. 1. For example, although not illustrated in FIG. 1, the reception device 20 may have a control circuit unit including an arithmetic theoretical operation element such as a DSP, an FPGA, or a microcomputer. For example, the control circuit unit can demodulate a reception signal.

More specifically, in the present embodiment, for example, as illustrated in FIG. 2, the transmission signal 400 includes the correlation sequence 402 at the head thereof and includes, after the correlation sequence 402, the transmission data 404 including information to be transmitted. Furthermore, the cross-correlation characteristic (correlation value) of the correlation sequence 402 can be expressed by, for example, the following Formula (1). In the present embodiment, the correlation sequence 402 preferably has a signal pattern in which the cross-correlation characteristic (correlation value) has a sharp peak in order to accurately calculate arrival time at which the reception device 20 has received the transmission signal 400. Therefore, in the present embodiment, for example, it is preferable to select a sequence xₖ of a length k of Formula (1) so that the cross-correlation characteristic has a sharp peak.

$${r}_{k} = \text{?} = A δ ( k ) = \{ \begin{matrix}A , & k = 0 \\ 0 , & k \neq 0\end{matrix} \qquad ( 1 )$$

$$\text{?} \text{indicates text missing or illegible when filed}$$

More specifically, in the present embodiment, for example, a preamble symbol defined in IEEE 802.15.4z-2020 can be used as the correlation sequence 402.

### <2.2 Calculation Method>

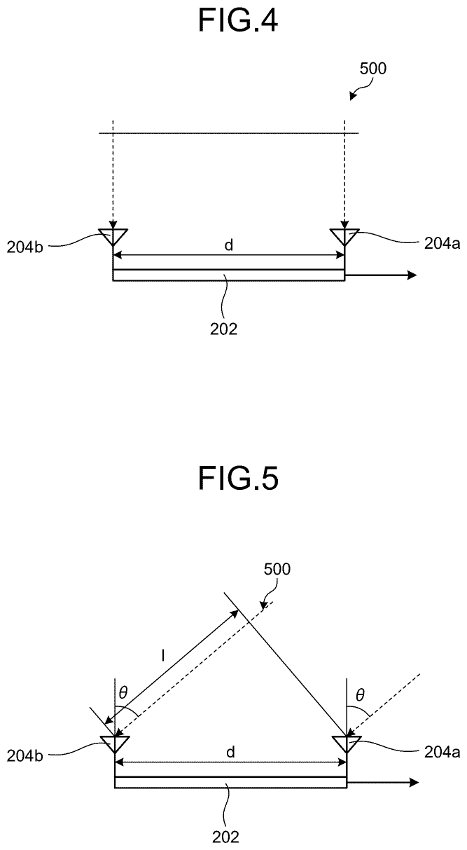

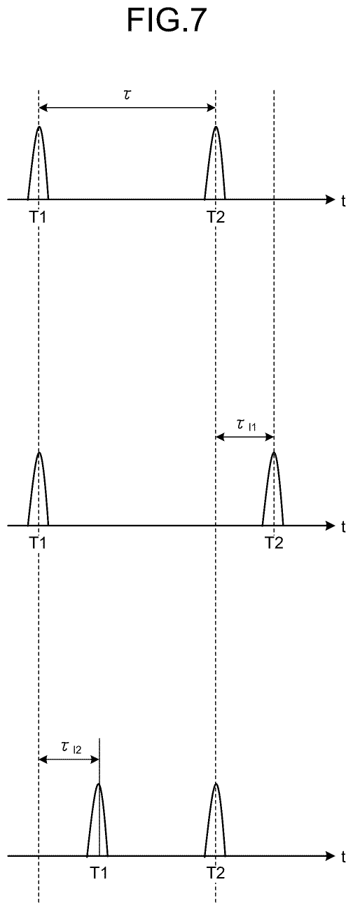

Next, a method of calculating an arrival angle according to the present embodiment will be described with reference to FIGS. 4 to 7. FIGS. 4 to 7 are explanatory diagrams for explaining the present embodiment. In detail, FIGS. 4 to 6 illustrate states in which the transmission signals 400 with various arrival angles are incident on the antenna component 200, and FIG. 7 illustrates cross-correlation characteristics obtained by a transmission signals 500 received in the states of FIGS. 4 to 6.

It is assumed in the examples illustrated in FIGS. 4 to 6 that antenna elements 204a and 204b of the antenna component 200 are installed apart from each other by a distance d, and are connected in series and linearly by the transmission line 202. Here, it is assumed that a length of the transmission line 202 between the antenna elements 204a and 204b is equal to the distance between the antenna elements 204a and 204b. Note that, in the present embodiment, the length of the transmission line 202 between the antenna elements 204a and 204b and the distance between the antenna elements 204a and 204b may not be equal, i.e., may be different. In FIGS. 4 to 6, the transmission signal 500 that is a plane wave arrives at the antenna component 200 in a direction from up to down in the drawing. It is also assumed in FIGS. 4 to 6 that an arrival angle of the transmission signal 500 with respect to the antenna component 200 is an angle θ.

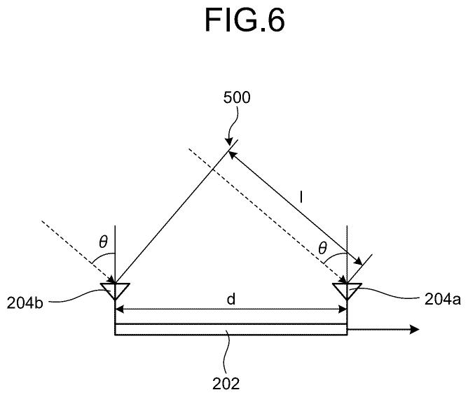

FIG. 4 illustrates a case where the angle θ of the arrival angle of the transmission signal 500 is 0 degrees. Note that, the angle θ of the arrival angle here refers to an angle formed by an axis perpendicular to the transmission line 202 and an incident direction of the transmission signal 500 (see FIGS. 5 and 6). At this time, the transmission signal 500 is simultaneously received by the antenna elements 204a and 204b. Then, the transmission signal 500 received by each of the antenna elements 204a and 204b is transmitted through the transmission line 202 and sequentially input to the correlator 230. A cross-correlation characteristic obtained by the correlator 230 at this time is illustrated in an upper part of FIG. 7. When the angle θ of the arrival angle of the transmission signal 500 is 0 degrees, in the cross-correlation characteristic output from the correlator 230, the transmission signal received by each antenna element 204 causes two peaks (pulses) to appear that have a time difference based on transmission time t required for transmission of the transmission signal 500 through the transmission line 202 having the length d.

In detail, as illustrated in the upper part of FIG. 7, a peak of a cross-correlation characteristic of the transmission signal 500 received by the antenna element 204b (output at time T2 in the upper part of FIG. 7) is output delayed by the transmission time t necessary for the transmission line 202 having the length d to transmit the transmission signal 500 after a peak of a cross-correlation characteristic of the transmission signal 500 received by the antenna element 204a (output at time T1 in the upper part of FIG. 7). Note that the transmission time t of the transmission line 202 is generally longer than a propagation time in which a radio wave propagates in a free space.

FIG. 5 illustrates a case where the angle θ of the arrival angle of the transmission signal 500 is a positive angle. At this time, the transmission signal 500 is sequentially received by the antenna element 204a and the antenna element 204b. Then, the transmission signal 500 received by each of the antenna elements 204a and 204b is transmitted through the transmission line 202 and sequentially input to the correlator 230. At this time, a cross-correlation characteristic obtained by the correlator 230 is illustrated in a middle part of FIG. 7.

In detail, as illustrated in the middle part of FIG. 7, a peak of a cross-correlation characteristic of the transmission signal 500 received by the antenna element 204a (output at time T2 in the middle part of FIG. 7) is output delayed by time obtained by combining τ₁₁ that is a propagation time for propagation through a path difference 1 in the space (see FIG. 5) and the transmission time t necessary for transmission through the transmission line 202 having the length d after a peak of a cross-correlation characteristic of the transmission signal 500 received by the antenna element 204a (output at the time T1 in the middle part of FIG. 7). In other words, when the angle θ of the arrival angle of the transmission signal 500 is a positive angle, a time difference between the two peaks of the cross-correlation characteristics output by the correlator 230 is T2−T1=τ+τ₁₁.

FIG. 6 illustrates a case where the angle θ of the arrival angle of the transmission signal 500 is a negative angle. At this time, the transmission signal 500 is sequentially received by the antenna element 204b and the antenna element 204a. Then, the transmission signal received by each of the antenna elements 204a and 204b is transmitted through the transmission line 202 and sequentially input to the correlator 230. At this time, a cross-correlation characteristic obtained by the correlator 230 is illustrated in a lower part of FIG. 7.

As illustrated in the lower part of FIG. 7, a peak of a cross-correlation characteristic of the transmission signal 500 received by the antenna element 204b (output at time T1 in the lower part of FIG. 7) is output delayed by time τ₁₂ that is a propagation time for propagation through a path difference 1 in the space (see FIG. 6) after the peak of the cross-correlation characteristic of the transmission signal received by the antenna element 204a (output at the time T1 in the upper part of FIG. 7) when the angle θ of the arrival angle is 0 degrees. On the other hand, a peak of a cross-correlation characteristic of the transmission signal 500 received by the antenna element 204b (output at time T2 in the lower part of FIG. 7) is output delayed by the transmission time τ necessary for transmission through the transmission line 202 having the length d after the peak of the cross-correlation characteristic of the transmission signal received by the antenna element 204a (output at the time T1 in the upper part of FIG. 7) when the angle θ of the arrival angle is 0 degrees. In other words, when the angle θ of the arrival angle of the transmission signal 500 has a negative angle, the time difference between the two peaks of the cross-correlation characteristic output by the correlator 230 is T2−T1=τ+τ₁₂.

As described in the foregoing, the time difference between the two peaks of the cross-correlation characteristic output by the correlator 230 changes depending on the angle θ of the arrival angle of the transmission signal 500.

Here, it is assumed that the length d of the transmission line 202 between the antenna elements 204a and 204b and the transmission time τ required for transmission through the transmission line 202 having the length d are known. Then, assuming that a speed of the radio wave in the free space is co, the angle θ of the arrival angle of the transmission signal 500 can be calculated from the time difference between the two peaks of the cross-correlation characteristic output by the correlator 230 using the following Formula (2).

$$d sin θ = l \qquad ( 2 )$$

$$θ = {sin}^{- 1} \frac{l}{d} = {sin}^{- 1} \frac{{c}_{0} \text{?}}{d}$$

$$\text{?} \text{indicates text missing or illegible when filed}$$

In this way, in the present embodiment, the angle θ of the arrival angle of the transmission signal 500 can be calculated on the basis of the time difference between the two peaks of the cross-correlation characteristic output by the correlator 230.

In the present embodiment, when the length d of the transmission line 202 between the antenna elements 204a and 204b and the transmission time τ required for transmission through the transmission line 202 having the length d are known, the angle θ of the arrival angle can be calculated. Therefore, the length d of the transmission line 202 between the antenna elements 204a and 204b and the like can be freely set without any restriction. As a result, according to the present embodiment, since it is possible to avoid narrowing the interval between the antenna elements 204, the probability that the plurality of antenna elements 204 is simultaneously shielded is low, and the reception device 20 can stably receive the transmission signal 500 and stably calculate the angle θ of the arrival angle.

Furthermore, in the present embodiment, it is not necessary to provide a phase detector in each of the plurality of antenna elements, and the angle θ of the arrival angle of the transmission signal 500 can be calculated by one correlator 230. Therefore, according to the present embodiment, the configuration of the reception device 20 can be simplified.

### <2.3 Antenna Component>

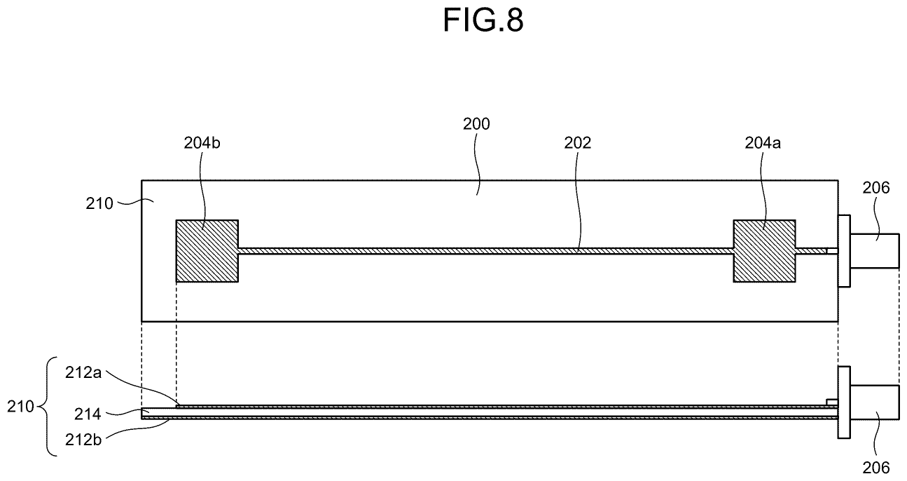

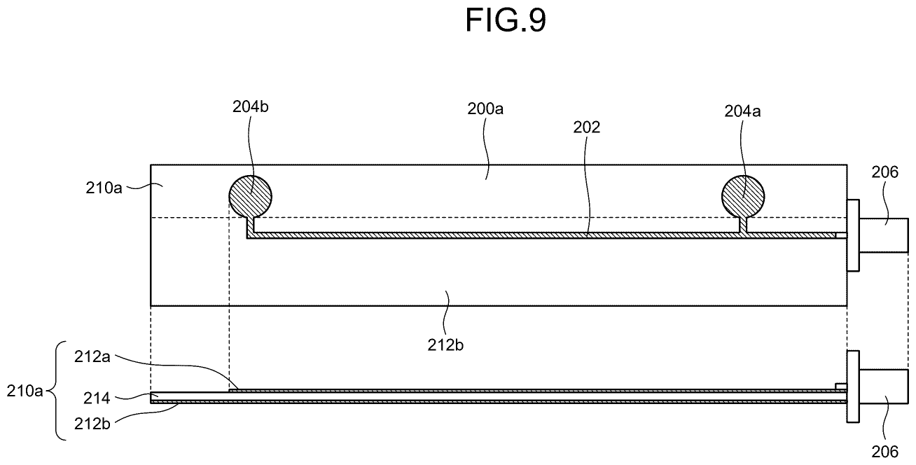

Next, a configuration of the antenna component 200 according to the present embodiment will be described with reference to FIGS. 8 and 9. FIG. 8 is a schematic diagram of the antenna component 200 according to the present embodiment. FIG. 9 is a schematic diagram of an antenna component 200a according to a modification example of the present embodiment, and in detail, plan views of the antenna components 200 and 200a are illustrated in upper parts of FIGS. 8 and 9, respectively, and side views of the antenna components 200 and 200a are illustrated in lower parts, respectively.

As described above, the antenna component 200 includes the plurality of antenna elements 204 that receives the transmission signal 500, and the transmission line 202 that connects the plurality of antenna elements 204 in series and transmits the transmission signal 500 received by each antenna element 204 to the reception circuit 220. More specifically, in the present embodiment, the antenna element 204 can be, for example, a patch antenna, a dipole antenna, a monopole antenna, a slot antenna, or the like.

Furthermore, in the present embodiment, as described above, a plurality of peaks of the cross-correlation characteristic of the transmission signal 500 received by each antenna element 204 appears at an output of the correlator 230 with a time difference based on the transmission time τ of the transmission signal 500 on the transmission line 202. Accordingly, in the present embodiment, in order to facilitate detection of this peak, it is preferable that the peaks appear at separable intervals. Then, the interval is determined on the basis of the transmission time τ of the transmission signal 500 on the transmission line 202. Therefore, in the present embodiment, it is preferable to select a material and structure of the transmission line 202 and a length between the plurality of antenna elements 204 that determine the transmission time τ of the transmission signal 500 in order to cause the peaks to appear at separable intervals.

In the present embodiment, for example, the transmission line 202 can be a coaxial cable, a microstrip line, a coplanar line, a slot line, a substrate integrated waveguide, a twisted pair line, or the like. Furthermore, in the present embodiment, the transmission line 202 may have a shape of a straight line that connects the plurality of antenna elements 204 with a straight line, a loop line having deflection or a loop, a meander line, a zigzag line, or the like. Furthermore, the transmission time τ of the transmission line 202 can be controlled by applying, for example, a metamaterial structure to the transmission line 202. In detail, in the present embodiment, the transmission time τ of the transmission line 202 can be freely controlled by, for example, providing the transmission line 202 with a structure or a pattern finer than a wavelength of the transmission signal 500 (metamaterial structure).

Specifically, FIG. 8 illustrates a configuration example of the antenna component 200 in which a microstrip line is used as the transmission line 202, and rectangular patch antennas are used as the two antenna elements 204a and 204b. In detail, the antenna component 200 has a substrate 210 having a laminated structure including a dielectric 214 and two copper foils (examples of a conductor) 212a and 212b sandwiching the dielectric 214. The substrate 210 is made of a printed (PCB) substrate in which wiring and the like are formed on a resin substrate, of a ceramic substrate, a silicon substrate, a glass substrate, or the like. In the present embodiment, by using a material having a high relative permittivity for the dielectric 214, the transmission speed can be reduced. The copper foil 212a constitutes a microstrip line or a patch antenna. Furthermore, one end of the transmission line 202 is electrically connected to a connector 206.

In addition, FIG. 9 illustrates a configuration example of the antenna component 200a using a microstrip line as the transmission line 202 and using a circular monopole antenna as the two antenna elements 204a and 204b. In detail, the antenna component 200a has a substrate 210a having the laminated structure including the dielectric 214, and the two copper foils 212a and 212b sandwiching the dielectric 214. The copper foil 212a constitutes the microstrip line or the monopole antenna, and the copper foil 212b is provided so as not to overlap with the antenna elements 204a and 204b.

Note that the antenna component 200 according to the present embodiment is not limited to the configuration examples illustrated in FIGS. 8 and 9.

As described in the foregoing, in the present embodiment, when the length d of the transmission line 202 between the antenna elements 204a and 204b and the transmission time τ required for transmission through the transmission line 202 having the length d are known, the angle θ of the arrival angle can be calculated. Therefore, the length d of the transmission line 202 between the antenna elements 204a and 204b, and the like can be freely set without any restriction. As a result, according to the present embodiment, since it is possible to avoid narrowing the interval between the antenna elements 204, the probability that the plurality of antenna elements 204 is simultaneously shielded is low, and the reception device 20 can stably receive the transmission signal 500 and stably calculate the angle θ of the arrival angle.

Furthermore, in the present embodiment, it is not necessary to provide a phase detector in each of the plurality of antenna elements, and the angle θ of the arrival angle of the transmission signal 500 can be calculated by one correlator 230. Therefore, according to the present embodiment, the configuration of the reception device 20 can be simplified.

### 3. Second Embodiment

In a second embodiment of the present disclosure, a reception device 20a has a function for measuring a length d of a transmission line 202 between antenna elements 204a and 204b. In the following, details of the present embodiment will be sequentially described.

### <3.1 Reception Device>

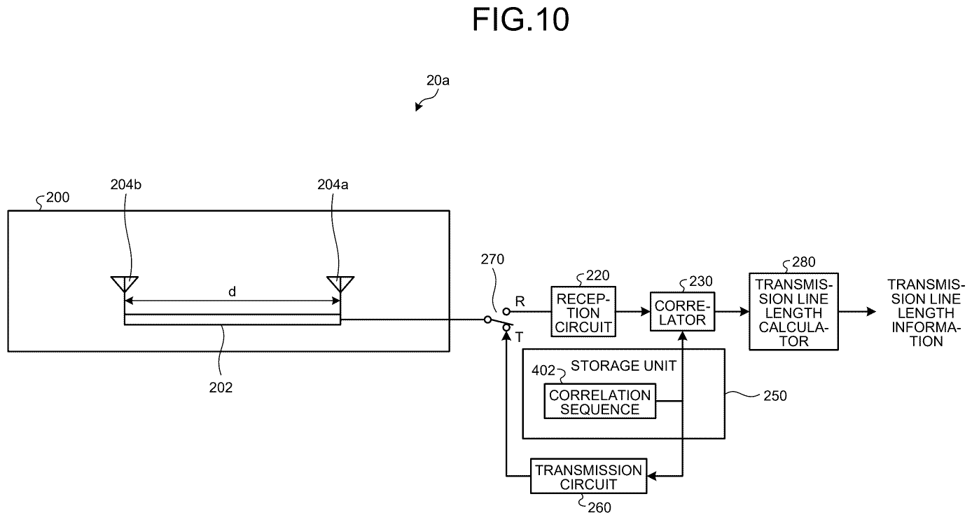

First, a configuration of the reception device 20a according to the present embodiment will be described with reference to FIG. 10. FIG. 10 is a block diagram of the reception device 20a according to the present embodiment. In detail, in the present embodiment, as illustrated in FIG. 10, the reception device 20a includes an antenna component 200, a reception circuit 220, a correlator 230, and a storage unit 250. Furthermore, the reception device 20a includes a transmission circuit 260, a radio frequency (RF) switch (second switch) 270, and a transmission line length calculator (transmission line length calculation unit) 280. Although in the following, each functional unit of the reception device 20a according to the present embodiment will be described, description of functional units common to the reception device 20 according to the first embodiment will be omitted here.

### ~Transmission Circuit 260~

The transmission circuit 260 can transmit a transmission signal 400 including a correlation sequence stored in advance in the storage unit 250 to the antenna component 200. In addition, the transmission circuit 260 can be configured with, for example, an oscillator (not illustrated) that generates a local oscillation signal having a desired frequency, a mixer (not illustrated) that converts a frequency of the transmission signal 400, a band-pass filter (not illustrated) that selectively passes a signal of a desired frequency, a power amplifier (not illustrated) that amplifies the transmission signal, and the like.

### ~RF Switch 270~

The RF switch 270 includes, for example, a semiconductor element, a resistance element, or the like, has one antenna component 200 side port (not illustrated), one transmission port T, and one reception port R, and can switch a port electrically connected to the antenna component 200 side port between the transmission port T and the reception port R. As illustrated in FIG. 10, the transmission circuit 260 is connected to the transmission port T of the RF switch 270, and the reception circuit 220 is connected to the reception port R of the RF switch 270. In the present embodiment, a directional coupler may be used instead of the RF switch 270.

### ~Transmission Line Length Calculator 280~

The transmission line length calculator 280 can calculate the length (transmission line length) d of the transmission line 202 between the plurality of antenna elements 204 on the basis of a difference in arrival time between the transmission signals 400 reflected from the plurality of antenna elements 204. For example, the transmission line length calculator 280 can be configured with, for example, an arithmetic theoretical operation element such as a DSP, an FPGA, or a microcomputer.

Note that the reception device 20a according to the present embodiment is not limited to the configuration example illustrated in FIG. 10.

### <3.2 Calculation Method>

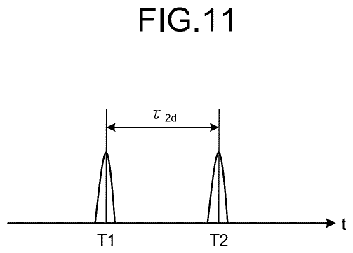

Next, a method of calculating the length d of the transmission line 202 between the plurality of antenna elements 204 in the present embodiment will be described with reference to FIG. 11. FIG. 11 is an explanatory diagram for explaining the present embodiment, and in detail, illustrates a cross-correlation characteristic obtained by the transmission signal 400 in the present embodiment.

Here, it is assumed that the antenna elements 204a and 204b of the antenna component 200 are connected in series by the transmission line 202 having the length d.

First, the reception device 20a switches a port electrically connected to the antenna component 200 side port of the RF switch 270 to the transmission port T, and transmits the transmission signal 400 to the antenna component 200. Next, the reception device 20a switches the port electrically connected to the antenna component 200 side port of the RF switch 270 to the reception port R. Then, the transmission signal 400 transmitted to the antenna component 200 is reflected by each of the antenna elements 204a and 204b of the antenna component 200, and is input to the reception circuit 220 and then to the correlator 230 via the RF switch 270.

At this time, a cross-correlation characteristic obtained by the correlator 230 is illustrated in FIG. 11. In detail, in the cross-correlation characteristic output from the correlator 230, due to the transmission signal 400 reflected by each of the antenna elements 204a and 204b, two peaks appear that have a time difference based on a transmission time τ_{2d} required for transmission in a length twice the length d of the transmission line 202 between the antenna elements 204a and 204b. Here, when the transmission signal 400 on the transmission line 202 is set to have a transmission speed Ct, the length d of the transmission line 202 between the antenna elements 204a and 204b can be expressed using the following Formula (3).

$${τ}_{2 d} = \frac{2 d}{{C}_{t}} \qquad ( 3 )$$

As described above, according to the present embodiment, the length d of the transmission line 202 between the antenna elements 204a and 204b can be measured by the reception device 20a.

### 4. Third Embodiment

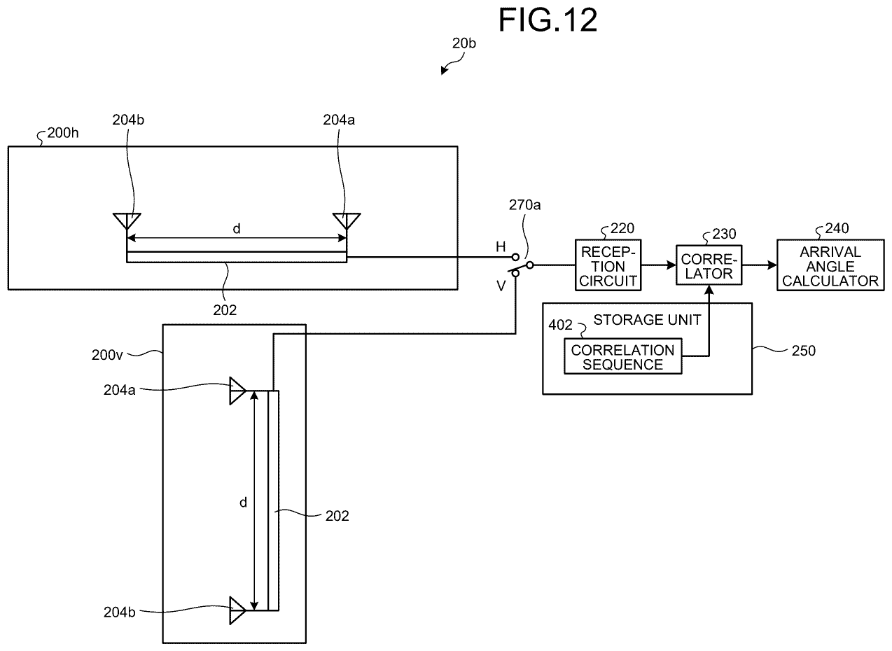

Next, a third embodiment of the present disclosure will be described with reference to FIG. 12. FIG. 12 is a block diagram of a reception device 20b according to the present embodiment. Although in the embodiment of the present disclosure described so far, the antenna component 200 is arranged one-dimensionally, in the third embodiment of the present disclosure, two antenna components 200 may be arranged two-dimensionally. In the present embodiment, by using the two antenna components 200 thus arranged two-dimensionally, it is possible to calculate an angle θ of an arrival angle in two directions of a transmission signal 400 incident on the antenna component 200.

In the present embodiment, as illustrated in FIG. 12, the reception device 20b mainly includes two antenna components (first and second antenna components) 200h and 200v, a reception circuit 220, a correlator 230, an arrival angle calculator 240, a storage unit 250, and an RF switch (first switch) 270a. Although in the following, each functional unit of the reception device 20b will be described, description of functional units common to the reception device 20 according to the first embodiment will be omitted here.

### ~Antenna Component 200h, 200v~

The antenna component (first antenna component) 200h has a plurality of antenna elements (first antenna elements) 204a and 204b aligned along a horizontal direction (first direction), and a transmission line (first transmission line) 202 that connects the antenna elements 204a and 204b in series. In addition, the antenna component (second antenna component) 200v has a plurality of antenna elements (second antenna elements) 204a and 204b aligned along a vertical direction (second direction) perpendicular to the horizontal direction, and a transmission line (second transmission line) 202 that connects the antenna elements 204a and 204b in series. In other words, in the present embodiment, two antenna components 200 according to the first embodiment are provided, one antenna component 200h being arranged along the horizontal direction, and the other antenna component 200v being arranged along the vertical direction. In the present embodiment, by using the two antenna components 200h and 200v arranged two-dimensionally, it is possible to calculate the angle θ of the arrival angle in the horizontal direction of the transmission signal 400 incident on the antenna component 200h and the angle θ of the arrival angle in the vertical direction of the transmission signal 400 incident on the antenna component 200v.

### ~RF Switch 270a~

The RF switch 270a includes, for example, a semiconductor element, a resistance element, or the like, and has one reception circuit 220 side port (not illustrated) and two antenna component 200 side ports H and V. Then, the RF switch 270a can switch a port electrically connected to one reception circuit 220 side port between the antenna component 200 side port H connected to the antenna component 200h and the antenna component 200 side port V connected to the antenna component 200v.

Therefore, in the present embodiment, in a case where the port electrically connected to the one reception circuit 220 side port is connected to the antenna component 200 side port H connected to the antenna component 200h, the angle θ of the arrival angle in the horizontal direction of the transmission signal 400 incident on the antenna component 200h can be calculated. By contrast, in a case where the port electrically connected to the one reception circuit 220 side port is connected to the antenna component 200 side port V connected to the antenna component 200v, the angle θ of the arrival angle in the vertical direction of the transmission signal 400 incident on the antenna component 200v can be calculated. Note that a method of calculating the angle θ of each arrival angle is similar to that of the first embodiment, and thus description thereof will be omitted here.

As described in the foregoing, by using the two antenna components 200h and 200v arranged two-dimensionally, the present embodiment makes it possible to calculate the angle θ of the arrival angle in the horizontal direction of the transmission signal 400 incident on the antenna component 200h and the angle θ of the arrival angle in the vertical direction of the transmission signal 400 incident on the antenna component 200v.

Note that the reception device 20b according to the present embodiment is not limited to the configuration example illustrated in FIG. 12, and may have, for example, three or more antenna components 200. Furthermore, in the present embodiment, the antenna component 200 is not limited to being arranged along the horizontal direction and the vertical direction, and the plurality of antenna components 200 may be provided along directions different from each other.

### 5. Fourth Embodiment

While in the third embodiment described above, the RF switch 270a is used, in a fourth embodiment of the present disclosure, a delay line may be used instead of the RF switch 270a. With this configuration, the present embodiment enables a reception device 20c to have a simple configuration. In the following, details of the present embodiment will be sequentially described.

### <5.1 Reception Device>

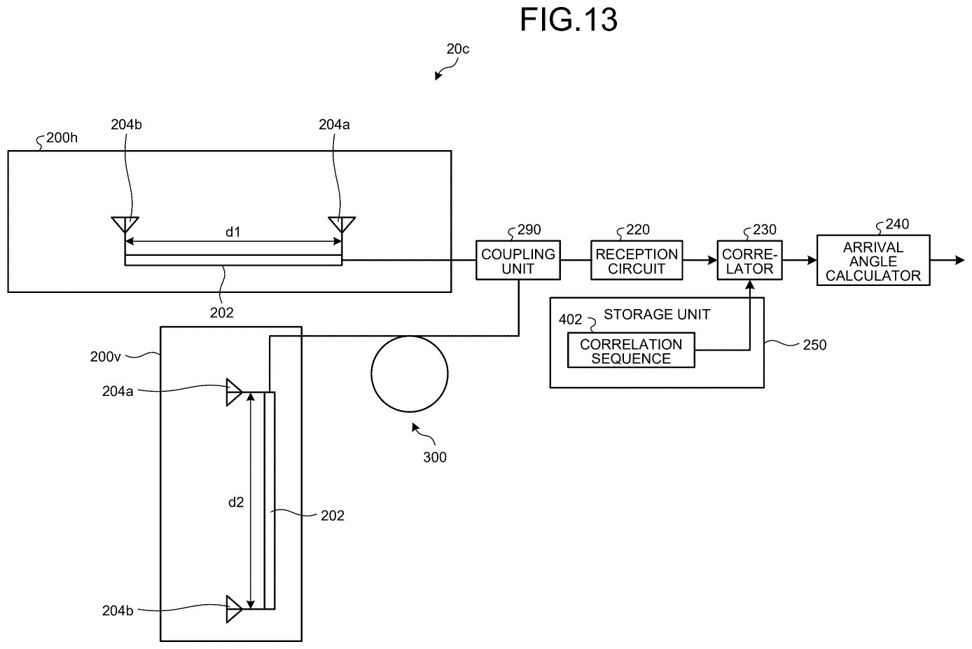

First, a configuration of the reception device 20c according to the present embodiment will be described with reference to FIG. 13. FIG. 13 is a block diagram of the reception device 20c according to the present embodiment.

In the present embodiment, as illustrated in FIG. 13, the reception device 20c includes two antenna components 200h and 200v, a reception circuit 220, a correlator 230, an arrival angle calculator 240, and a storage unit 250. The reception device 20c further includes a coupling unit (coupler) 290 and a delay line 300. In the following, while each functional unit of the reception device 20c will be described, description of functional units common to the reception devices 20 and 20b according to the first and third embodiments will be omitted here.

### ~Coupling Unit 290~

The coupling unit 290 can couple the antenna component 200h and the antenna component 200v, connect them to the reception circuit 220, and transmit a transmission signal 400 from the antenna component 200h and the antenna component 200v to the reception circuit 220.

### ~Delay Line 300~

The delay line 300 is provided between one of the two antenna components 200h and 200v and the reception circuit 220, and can delay the transmission signal 400 from one of the two antenna components 200h and 200v. Similarly to, for example, a transmission line 202, the delay line 300 can be a coaxial cable, a microstrip line, a coplanar line, a slot line, a substrate integrated waveguide, a twisted pair line, or the like. Furthermore, in the present embodiment, the delay line 300 may have a shape of a straight line, a loop line having deflection or a loop, a meander line, a zigzag line, or the like. Furthermore, transmission time may be adjusted by applying, for example, a metamaterial structure to the delay line 300.

In the present embodiment, by using the delay line 300, even when the transmission signals 400 from the antenna component 200h and the antenna component 200v are received by one reception circuit 220, it is possible to separate, by a delay caused by the delay line 300, a peak of a cross-correlation characteristic due to the transmission signal 400 from the antenna component 200h and a peak of a cross-correlation characteristic due to the transmission signal 400 from the antenna component 200v. Specifically, in the present embodiment, use of the delay line 300 enables one reception circuit 220 and one correlator 230 to calculate an angle θ of an arrival angle in the horizontal direction of the transmission signal 400 incident on the antenna component 200h and an angle θ of an arrival angle in the vertical direction of the transmission signal 400 incident on the antenna component 200v.

Note that the reception device 20c according to the present embodiment is not limited to the configuration example illustrated in FIG. 13.

### <5.2 Calculation Method>

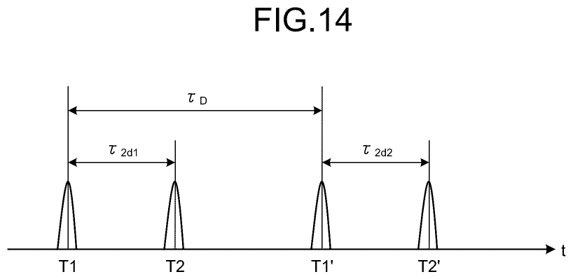

Next, a method of calculating the angle θ of the arrival angle according to the present embodiment will be described with reference to FIG. 14. FIG. 14 is an explanatory diagram for explaining the present embodiment, and in detail, illustrates a cross-correlation characteristic in the present embodiment.

A cross-correlation characteristic obtained by the correlator 230 in the present embodiment is illustrated in FIG. 14. In detail, in the cross-correlation characteristic output from the correlator 230, first, there appear two peaks (in FIG. 14, output at times T1 and T2) based on the transmission signal 400 received by each of antenna elements 204a and 204b of the antenna component 200h. Next, there appear two peaks (in FIG. 14, output at times T1′ and T2′) based on the transmission signal 400 received by each of antenna elements 204a and 204b of the antenna component 200v with a time difference based on transmission time to required for transmission for a length of the delay line 300.

Therefore, in the present embodiment, similarly to the first embodiment, the angle θ of the arrival angle in the horizontal direction of the transmission signal 400 incident on the antenna component 200h can be calculated using a time difference τ_{2d1} between the two peaks of the cross-correlation characteristic output by the correlator 230. Furthermore, in the present embodiment, similarly to the first embodiment, the angle θ of an arrival angle in the horizontal direction of the transmission signal 400 incident on the antenna component 200v can be calculated using a time difference τ_{2d2} between the peaks of the cross-correlation characteristic output by the correlator 230.

As described in the foregoing, in the present embodiment, use of the delay line 300, instead of the RF switch 270a, enables one reception circuit 220 and one correlator 230 to calculate the angle θ of the arrival angle in the horizontal direction of the transmission signal 400 incident on the antenna component 200h and the angle θ of the arrival angle in the vertical direction of the transmission signal 400 incident on the antenna component 200v. Therefore, the present embodiment enables the reception device 20c to have a simple configuration.

### 6. Fifth Embodiment

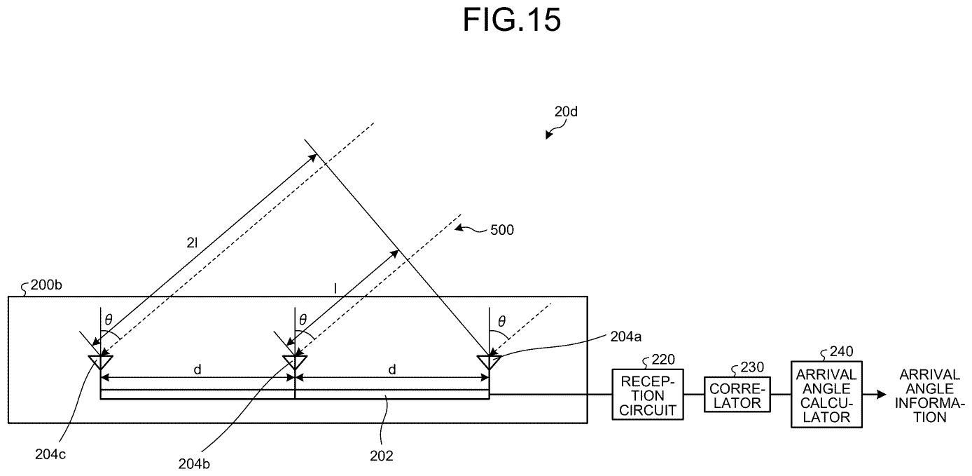

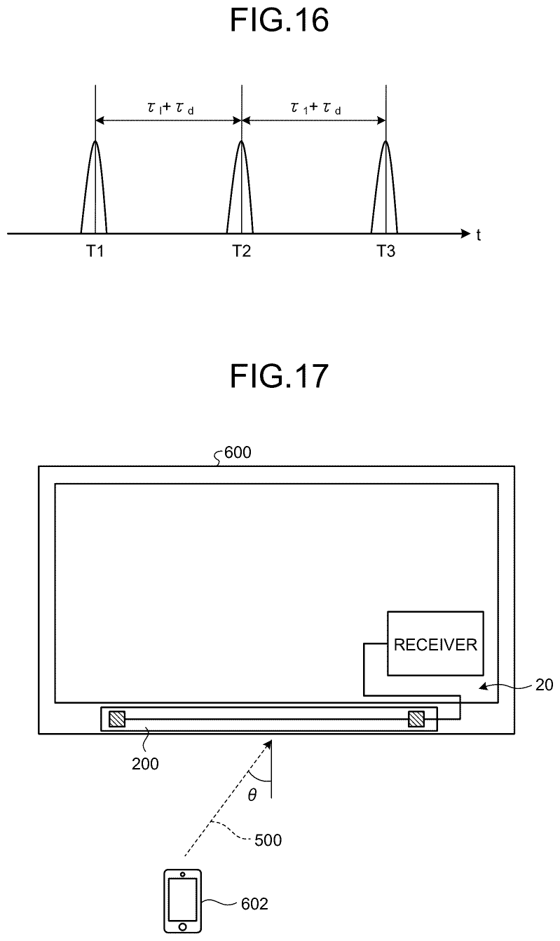

Next, a fifth embodiment of the present disclosure will be described with reference to FIGS. 15 and 16. FIG. 15 is a block diagram of a reception device 20d according to the present embodiment, and FIG. 16 is an explanatory diagram for explaining the present embodiment, and in detail, illustrates a cross-correlation characteristic according to the present embodiment.

In the embodiment of the present disclosure described so far, the number of the antenna elements 204 of the antenna component 200 is two. However, in the embodiment of the present disclosure, the number of the antenna elements 204 is not limited to two, and may be three or more. Therefore, the fifth embodiment of the present disclosure using an antenna component 200 having three antenna elements 204 will be here described.

First, a configuration of the reception device 20d according to the present embodiment will be described with reference to FIG. 15. In the present embodiment, as illustrated in FIG. 15, the reception device 20d includes an antenna component 200b, a reception circuit 220, a correlator 230, an arrival angle calculator 240, and a storage unit 250.

Furthermore, in the present embodiment, the antenna component 200b includes three antenna elements 204a, 204b, and 204c that receive a transmission signal 400, as described above. Then, the antenna component 200b includes a transmission line 202 that connects the plurality of antenna elements 204a, 204b, and 204c in series and transmits the transmission signal 400 received by each of the antenna elements 204a, 204b, and 204c to the reception circuit 220. In addition, it is assumed that the three antenna elements 204a, 204b, and 204c are aligned along a predetermined direction with the transmission line 202 having a length d provided therebetween.

A cross-correlation characteristic obtained by the correlator 230 in the present embodiment is illustrated in FIG. 16. In detail, in the cross-correlation characteristic output from the correlator 230, there appear three peaks (in FIG. 16, output at times T1, T2, T3) based on the transmission signal 400 received by each of the antenna elements 204a, 204b, and 204c of the antenna component 200. A peak (output at the time T2 in FIG. 16) of the transmission signal 400 received by the antenna element 204b is output delayed by a time obtained by combining propagation time τ₁₁ which is time for propagation through a path difference 1 (see FIG. 15) and transmission time τ required for transmission on the transmission line 202 having the length d after a peak (output at the time T1 in FIG. 16) obtained by the transmission signal 400 received by the antenna element 204a. Furthermore, a peak (output at the time T3 in FIG. 16) of the transmission signal 400 received by the antenna element 204c is output delayed by a time obtained by combining propagation time τ₁₁ which is time for propagation through the path difference 1 (see FIG. 15) and the transmission time τ required for transmission on the transmission line 202 having the length d after the peak (output at the time T2 in FIG. 16) of the transmission signal 400 received by the antenna element 204b. Note that a method of calculating an angle θ of an arrival angle is similar to that of the first embodiment, and thus description thereof will be omitted here.

In the present embodiment, by combining and using the above-described three peaks, it is possible to suppress an increase in a signal-to-noise ratio (SNR) with respect to a signal and to improve accuracy of calculating the angle θ of the arrival angle. For example, even in a case where an intensity of the transmission signal 400 received by the reception device 20 becomes weak due to an increased distance of a transmission device 10 or the like, the present embodiment enables accurate calculation of the angle θ of the arrival angle. Furthermore, according to the present embodiment, even in a case where one of the antenna elements 204 is shielded to prevent reception of the transmission signal 400, when the transmission signal 400 can be received by the remaining two antenna elements 204, the angle θ of the arrival angle can be calculated. In other words, according to the present embodiment, the angle θ of the arrival angle can be stably calculated even in various environments.

Note that, in the present embodiment, the number of the antenna elements 204 is not limited to three as illustrated in FIG. 15, and may be three or more, and is not particularly limited.

### 7. Conclusion

As described in the foregoing, according to the embodiments of the present disclosure, when the length d of the transmission line 202 between the antenna elements 204a and 204b and the transmission time τ required for transmission through the transmission line 202 having the length d are known, the angle θ of the arrival angle can be calculated. Therefore, the length d of the transmission line 202 between the antenna elements 204a and 204b and the like can be freely set without any restriction. As a result, according to the present embodiment, since it is possible to avoid narrowing the interval between the antenna elements 204, the probability that the plurality of antenna elements 204 is simultaneously shielded is low, and the reception device 20 can stably receive the transmission signal 500 and stably calculate the angle θ of the arrival angle. Furthermore, in the present embodiment, it is not necessary to provide a phase detector in each of the plurality of antenna elements, and the angle θ of the arrival angle of the transmission signal 500 can be calculated by one correlator 230. Therefore, according to the present embodiment, the configuration of the reception device 20 can be simplified.

### 8. Application Example

For example, the technique according to the present disclosure may be applied to a display unit or the like of various electronic apparatuses. Therefore, an example of an electronic apparatus to which the present technique can be applied will be described below.

### Application Example 1

First, description will be made of an example in which the reception device 20 according to the embodiment of the present disclosure is mounted on a television device 600 with reference to FIG. 17. FIG. 17 is an explanatory diagram for explaining an application example 1 of the present embodiment.

In the present application example 1, as illustrated in FIG. 17, the transmission device 10 according to the embodiment of the present disclosure is a smartphone 602, and the reception device 20 is mounted on the television device 600. In detail, the antenna component 200 according to the embodiment of the present disclosure is mounted around a display screen of the television device 600, and other functional units of the reception device 20 are built in, for example, a control unit (not illustrated) of the television device 600. Then, in the present application example 1, the transmission signal 400 is transmitted from the smartphone 602 to the television device 600, and the reception device 20 can specify a direction of the smartphone 602 with respect to the television device 600 by calculating the angle θ of the arrival angle of the transmission signal 400.

For example, in a case where a preamble symbol defined by IEEE 802.15.4 HRP UWB Ch9 is used as the correlation sequence 402, the frequency of the transmission signal 400 is, for example, 7987.2 MHz. This corresponds to a wavelength of about 3.75 cm. In addition, a width of the peak of the cross-correlation characteristic output by the correlator 230 is about 2 ns.

In addition, a horizontal width of the television device 600 having a size of 50 inches is, for example, about 110 cm. Therefore, in the present application example 1, the length d of the transmission line 202 between the antenna elements 204 of the antenna component 200 is set to 110 cm in accordance with the horizontal width of the television device 600 having the size of 50 inches.

Furthermore, in a case where a coaxial cable (relative permittivity εᵣ=2.26) is used as the transmission line 202, a transmission speed of the transmission line 202 is 2×10⁸ m/s. Therefore, since the transmission time τ_{d} of the transmission signal 400 received by the antenna element 204b of the antenna component 200 on the transmission line 202 of 110 cm is 5.5 ns, a time difference between two peaks of a cross-correlation characteristic output by the correlator 230 can be observed (i.e., the two peaks are separable), and thus the angle θ of the arrival angle can be calculated.

Note that although in the example illustrated in FIG. 17, the antenna component 200 is installed in the horizontal direction along the display screen of the television device 600, the present application example 1 is not limited to such installation. In the present application example 1, for example, the antenna component 200 may be installed in the vertical direction along the display screen of the television device 600, or may be installed two-dimensionally along both the horizontal direction and the vertical direction.

### Application Example 2

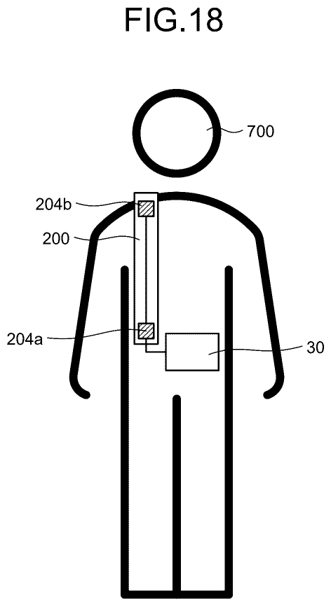

Next, description will be made of an example in which the reception device 20 according to the embodiment of the present disclosure is mounted on a human body 700 with reference to FIG. 18. FIG. 18 is an explanatory diagram for explaining an application example 2 of the present embodiment.

In the present application example 2, for example, as illustrated in FIG. 18, the antenna component 200 according to the embodiment of the present disclosure is mounted on a back of the human body 700. Specifically, the antenna component 200 is mounted on the back of the human body 700 such that the antenna element 204a of the antenna component 200 is located at a position of a waist of the human body 700 and the antenna element 204b is located at a position of a shoulder. When the antenna elements 204a and 204b can be mounted in a manner as described above, the distance d between the antenna elements 204a and 204b is considered to be about several 10 cm.

Then, in a case, for example, where a preamble symbol defined by IEEE 802.15.4 HRP UWB Ch9 is used as the correlation sequence 402, the frequency of the transmission signal 400 is, for example, 7987.2 MHz. This corresponds to a wavelength of about 3.75 cm. In other words, the length d of the transmission line 202 between the antenna elements 204a and 204b enables two peaks having an observable time difference to be generated in a cross-correlation characteristic. Therefore, also in the present application example 2, the angle θ of the arrival angle can be calculated.

Furthermore, in the present application example 2, it is assumed that the antenna component 200 is used not only for calculating the angle θ of the arrival angle but also for receiving the transmission data 404 and the like. In such a case, since the antenna component 200 has the two antenna elements 204a and 204b, even when any one of the antenna elements 204a and 204b is shielded to prevent reception of a signal, the signal can be received by the other of the antenna elements 204a and 204b. Therefore, in the present application example 2, the antenna component 200 according to the embodiment of the present disclosure sufficiently exerts a space diversity effect, and enables stable communication to be maintained.

Note that the technique according to the present disclosure may be applied to a smartphone, a tablet, a wearable terminal, an in-vehicle wireless module, and the like, and may be further applied to a moving body. Here, the moving body may be an automobile, an electric vehicle, a hybrid electric vehicle, a motorcycle, a bicycle, a personal mobility, an airplane, a drone, a ship, a robot (mobile robot), a construction machine, an agricultural machine (tractor), or the like. In addition, the moving body may include an autonomously moving object such as a person or an animal.

### 9. Supplement

Although the preferred embodiments of the present disclosure have been described in detail with reference to the accompanying drawings in the foregoing, the technical scope of the present disclosure is not limited to such examples. It is obvious that a person having ordinary knowledge in the technical field of the present disclosure can conceive various changes or modifications within the scope of the technical idea described in the claims, and it is naturally understood that these also belong to the technical scope of the present disclosure.

Furthermore, the effects described in the present specification are merely illustrative or exemplary, and are not restrictive. In other words, the technique according to the present disclosure can exhibit other effects obvious to those skilled in the art from the description of the present specification together with or instead of the above effects.

Note that the present technique can also have the following configurations.

(1) A reception device comprising:
an antenna component including a plurality of antenna elements that receives a predetermined radio wave transmitted from a predetermined transmission device, and a transmission line that connects the plurality of antenna elements in series and transmits a radio wave received by each of the antenna elements;
a correlator that acquires the radio wave via the transmission line and calculates a correlation between the radio wave received by each of the antenna elements and the predetermined radio wave; and
an arrival direction calculation unit that calculates an arrival direction of the radio wave on the basis of the calculated correlation.

(2) The reception device according to (1), wherein the predetermined radio wave includes a correlation sequence.

(3) The reception device according to (2), further comprising:
a storage unit that stores the correlation sequence in advance, wherein
the correlator calculates the correlation between the radio wave received by each of the antenna elements and the predetermined radio wave on the basis of the correlation sequence stored in advance.

(4) The reception device according to any one of (1) to (3), wherein
the arrival direction calculation unit calculates an arrival angle of the radio wave using a difference between arrival times of the radio waves received by the respective antenna elements obtained on the basis of the calculated correlation, and a length of the transmission line between the plurality of antenna elements.

(5) The reception device according to any one of (1) to (4), wherein the antenna element is a patch antenna, a dipole antenna, a monopole antenna, or a slot antenna.

(6) The reception device according to any one of (1) to (5), wherein the transmission line is a coaxial cable, a microstrip line, a coplanar line, a slot line, a substrate integrated waveguide, or a twisted pair line.

(7). The reception device according to any one of (1) to (5), wherein the transmission line has a shape of a straight line, a loop line, a meander line, or a zigzag line.

(8) The reception device according to any one of (1) to (5), wherein the transmission line is configured with a metamaterial structure.

(9) The reception device according to any one of (1) to (5), wherein the antenna component has a laminated structure including a dielectric and a plurality of conductors sandwiching the dielectric.

(10) The reception device according to any one of (1) to (9), wherein the antenna component includes two of the antenna elements.

(11) The reception device according to any one of (1) to (9), wherein the antenna component includes three of the antenna elements.

(12) The reception device according to any one of (1) to (9), further comprising:
a reception circuit that is provided between the transmission line and the correlator and converts the radio wave received by each of the antenna elements into a baseband signal.

(13) The reception device according to (12), wherein
the antenna component has:
a first antenna component including a plurality of first antenna elements aligned along a first direction and a first transmission line connecting the plurality of first antenna elements in series; and
a second antenna component including a plurality of second antenna elements aligned along a first direction different from the first direction, and a second transmission line connecting the plurality of second antenna elements in series.

(14) The reception device according to (13), further comprising a first switch that switches a connection destination of the reception circuit between the first antenna component and the second antenna component.

(15) The reception device according to (13), further comprising a delay line provided between one of the first antenna component and the second antenna component and the reception circuit.

(16) The reception device according to (15), further comprising a coupler that couples the first antenna component and the second antenna component to connect to the reception circuit.

(17) The reception device according to (12),
further comprising:
a transmission circuit that transmits the predetermined radio wave;
a second switch that switches a connection destination of the antenna component between the reception circuit and the transmission circuit; and
a transmission line length calculation unit that calculates a length of the transmission line between the plurality of antenna elements on the basis of the predetermined radio wave transmitted from the transmission circuit and reflected by each of the plurality of antenna elements.

(18) A reception method wherein
a reception device:
receives a predetermined radio wave transmitted from a predetermined transmission device via a plurality of antenna elements;
acquires the radio wave via a transmission line that connects the plurality of antenna elements in series and transmits a radio wave received by each of the antenna elements;
calculates a correlation between the radio wave received by each of the antenna elements and the predetermined radio wave; and
calculates an arrival direction of the radio wave on the basis of the calculated correlation.

(19) A transmission/reception system including:
a transmission device and a reception device, wherein
the reception device has:
an antenna component including a plurality of antenna elements that receives a predetermined radio wave transmitted from the transmission device, and a transmission line that connects the plurality of antenna elements in series and transmits a radio wave received by each of the antenna elements;
a correlator that acquires the radio wave via the transmission line and calculates a correlation between the radio wave received by each of the antenna elements and the predetermined radio wave; and
an arrival direction calculation unit that calculates an arrival direction of the radio wave on the basis of the calculated correlation.

### REFERENCE SIGNS LIST

1 TRANSMISSION/RECEPTION SYSTEM
10 TRANSMISSION DEVICE
20, 20a, 20b, 20c, 20d RECEPTION DEVICE
100, 250 STORAGE UNIT
110 TRANSMISSION CIRCUIT
120 TRANSMISSION ANTENNA
200, 200a, 200b, 200h, 200v ANTENNA COMPONENT
202 TRANSMISSION LINE
204a, 204b, 204c ANTENNA ELEMENT
206 CONNECTOR
210, 210a SUBSTRATE
212a, 212b COPPER FOIL
214 DIELECTRIC
220 RECEPTION CIRCUIT
230 CORRELATOR
240 ARRIVAL ANGLE CALCULATOR
260 TRANSMISSION CIRCUIT
270, 270a RF SWITCH
280 TRANSMISSION LINE LENGTH CALCULATOR
290 COUPLING UNIT
300 DELAY LINE
400, 500 TRANSMISSION SIGNAL
402 CORRELATION SEQUENCE
404 TRANSMISSION DATA
600 TELEVISION DEVICE
602 SMARTPHONE
700 HUMAN BODY

1. A reception device comprising:
an antenna component including a plurality of antenna elements that receives a predetermined radio wave transmitted from a predetermined transmission device, and a transmission line that connects the plurality of antenna elements in series and transmits a radio wave received by each of the antenna elements;
a correlator that acquires the radio wave via the transmission line and calculates a correlation between the radio wave received by each of the antenna elements and the predetermined radio wave; and
an arrival direction calculation unit that calculates an arrival direction of the radio wave on the basis of the calculated correlation.

2. The reception device according to claim 1, wherein the predetermined radio wave includes a correlation sequence.

3. The reception device according to claim 2, further comprising:
a storage unit that stores the correlation sequence in advance, wherein
the correlator calculates the correlation between the radio wave received by each of the antenna elements and the predetermined radio wave on the basis of the correlation sequence stored in advance.

4. The reception device according to claim 1, wherein
the arrival direction calculation unit calculates an arrival angle of the radio wave using a difference between arrival times of the radio waves received by the respective antenna elements obtained on the basis of the calculated correlation, and a length of the transmission line between the plurality of antenna elements.

5. The reception device according to claim 1, wherein the antenna element is a patch antenna, a dipole antenna, a monopole antenna, or a slot antenna.

6. The reception device according to claim 1, wherein the transmission line is a coaxial cable, a microstrip line, a coplanar line, a slot line, a substrate integrated waveguide, or a twisted pair line.

7. The reception device according to claim 1, wherein the transmission line has a shape of a straight line, a loop line, a meander line, or a zigzag line.

8. The reception device according to claim 1, wherein the transmission line is configured with a metamaterial structure.

9. The reception device according to claim 1, wherein the antenna component has a laminated structure including a dielectric and a plurality of conductors sandwiching the dielectric.

10. The reception device according to claim 1, wherein the antenna component includes two of the antenna elements.

11. The reception device according to claim 1, wherein the antenna component includes three of the antenna elements.

12. The reception device according to claim 1, further comprising:
a reception circuit that is provided between the transmission line and the correlator and converts the radio wave received by each of the antenna elements into a baseband signal.

13. The reception device according to claim 12, wherein
the antenna component has:
a first antenna component including a plurality of first antenna elements aligned along a first direction and a first transmission line connecting the plurality of first antenna elements in series; and
a second antenna component including a plurality of second antenna elements aligned along a first direction different from the first direction, and a second transmission line connecting the plurality of second antenna elements in series.

14. The reception device according to claim 13, further comprising a first switch that switches a connection destination of the reception circuit between the first antenna component and the second antenna component.

15. The reception device according to claim 13, further comprising a delay line provided between one of the first antenna component and the second antenna component and the reception circuit.

16. The reception device according to claim 15, further comprising a coupler that couples the first antenna component and the second antenna component to connect to the reception circuit.

17. The reception device according to claim 12,
further comprising:
a transmission circuit that transmits the predetermined radio wave;
a second switch that switches a connection destination of the antenna component between the reception circuit and the transmission circuit; and
a transmission line length calculation unit that calculates a length of the transmission line between the plurality of antenna elements on the basis of the predetermined radio wave transmitted from the transmission circuit and reflected by each of the plurality of antenna elements.

18. A reception method wherein
a reception device:
receives a predetermined radio wave transmitted from a predetermined transmission device via a plurality of antenna elements;
acquires the radio wave via a transmission line that connects the plurality of antenna elements in series and transmits a radio wave received by each of the antenna elements;
calculates a correlation between the radio wave received by each of the antenna elements and the predetermined radio wave; and
calculates an arrival direction of the radio wave on the basis of the calculated correlation.

19. A transmission/reception system including:
a transmission device and a reception device, wherein
the reception device has:
an antenna component including a plurality of antenna elements that receives a predetermined radio wave transmitted from the transmission device, and a transmission line that connects the plurality of antenna elements in series and transmits a radio wave received by each of the antenna elements;
a correlator that acquires the radio wave via the transmission line and calculates a correlation between the radio wave received by each of the antenna elements and the predetermined radio wave; and
an arrival direction calculation unit that calculates an arrival direction of the radio wave on the basis of the calculated correlation.
